(19) United States
(12) Patent Application Publication
(10) Pub. No.: US 2026/0118312 A1
(43) Pub. Date: Apr. 30, 2026

(54) MICROWELL SENSOR AND REFERENCE ELECTRODE SEMICONDUCTOR STRUCTURES AND METHODS OF FORMING SAME

(71) Applicant: Taiwan Semiconductor Manufacturing Company, LTD., Hsinchu (TW)

(72) Inventors: Cheng-Chun Juan, Taipei (TW); Pin-Hsien Lee, Keelung (TW); Yi-Ping Tsai, Hsinchu (TW)

(21) Appl. No.: 18/928,385

(22) Filed: Oct. 28, 2024

(51) Int. Cl. G01N 27/414; H01L 27/088; H01L 29/66

(52) U.S. Cl. CPC G01N 27/4145; G01N 27/4148; H10D 30/031; H10D 84/83

(57) ABSTRACT

A semiconductor biologically sensitive semiconductor device fabrication method and structure includes a biosensor microwell or well transistor and a reference electrode transistor; a biosensor microwell or well into which a biological material may be selectively introduced and a reference electrode cavity into which a reference material may be selectively introduced; a biologically sensitive layer within the biosensor microwell or well that is reactive to the biological material; and wherein the reference electrode cavity is located proximate to the biosensor microwell or well.

### BACKGROUND

The following relates to the semiconductor arts, and in particular, to a biological material sensing semiconductor device and/or a method for manufacturing the same.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A diagrammatically illustrates a top view of a biological material sensing semiconductor device in accordance with some example embodiments disclosed herein (Embodiment 1A) which has a polygon shaped top well cup and a polygon shaped reference electrode cavity, and FIG. 1B diagrammatically illustrates a cross-section view of the biological material sensing semiconductor device shown in FIG. 1A, taken along section line A-A.

FIG. 2 illustrates a top view of a biochip including a two-dimensional array of biological material sensing semiconductor devices in accordance with some example embodiments disclosed herein (Embodiment 1B) which have polygon shaped top well cups and polygon shaped reference electrode cavities.

FIG. 3A illustrates a top view of another biochip including a two-dimensional array of biological material sensing semiconductor devices in accordance with some example embodiments disclosed herein (Embodiment 1C) which have polygon shaped top well cups and polygon shaped reference electrode cavities, wherein the biochip further includes grouping of biosensors and reference electrodes, and a dummy electrode structure and FIG. 3B illustrates a cross-section view of the biochip shown in FIG. 3A, taken along section line B-B.

FIG. 4 illustrates a top view of another biochip including a two-dimensional array of biological material sensing semiconductor devices in accordance with some example embodiments disclosed herein which have circular shaped top well cups, and circular shaped reference electrode cavities (Embodiment 2A) and further includes dummy reference electrodes (Embodiment 2B).

FIG. 5 illustrates a top view of another biochip including a two-dimensional array of biological material sensing semiconductor devices in accordance with some example embodiments disclosed herein wherein the biochip includes grouping (Embodiment 2C), and the biochip includes circular shaped top well cups, circular shaped reference electrode cavities and further includes dummy reference electrodes.

FIG. 6 is another diagrammatical illustration depicting a cross-section view of a biological material sensing semiconductor device in accordance with some embodiments disclosed herein.

FIG. 7 is a flow chart showing a method of fabricating a biological material sensing semiconductor device in accordance with some embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer” as used herein, may include a single layers or multiple layers.

The term “intermetal dielectric” (IMD) film or layer, as used herein, refers to a dielectric/ insulation material(s) layer between two metal layers.

The term “interlayer dielectric” (ILD) layer, as used herein, refers to an insulating structure of material(s) placed between two conductive layers.

The term “proximately” as used herein to, as it relates to a reference electrode cavity “proximately” located adjacent to a biosensor well, refers to a substantially close noncontact location of the reference electrode cavity relative to the biosensor well.

The term “cavity” as used herein is defined to include, but not be limited to, a cavity, microcavity, microwell and/or well.

Generally, in accordance with some embodiments described herein, a biosensor and/or biosensing semiconductor device, including a reference electrode structure, is disclosed for sensing and/or detecting bio-entities, biomolecules, and/or biological materials. Suitably, the biosensor or biosensing semiconductor device operates on the basis of electronic and/or electrochemical detection principles. In some suitable embodiments, the biosensor and/or biosensing semiconductor device may comprise one or more or more transistors, for example, such a field-effect transistor (FET), a metal-oxide-semiconductor FET (MOSFET), biosensor FET (Bio-FET), ion-sensitive FET (ISFET) or the like. In some suitable embodiments, the detection can be performed by detecting the bio-entities, biomolecules and/or biological materials themselves (also referred to as analytes), or through interaction and/or reaction between specified reactants and bio-entities, biomolecules, biological materials and/or analytes. Advantageously, in some suitable embodiments, the biosensor and/or biosensing semiconductor device may be fabricated using semiconductor manufacturing processes, can quickly convert electric signals, and may be easily applied to integrated circuits (ICs) and microelectromechanical systems (MEMS).

In some suitable embodiments, a biosensing semiconductor device, i.e., biosensor, combines a biological material sensing layer or surface with a sensing device or sensor, for example, such as a suitable FET. In addition, the biosensor semiconductor device combines a reference electrode with the biological material sensing layer or surface and sensing device or sensor, as well as other circuitry operatively connected to the reference electrode, including a top surface cavity for accepting a reference material and generating a reference or threshold potential/voltage, or other electrical signal, for comparison with a biosensor electrical signal generated by a sampled biomaterial placed in a microwell or well of the biosensor. In some suitable embodiments, the biosensing semiconductor device may comprise a biochip including a plurality of such biosensors. In practice, the biosensor or biosensing semiconductor device includes an open-ended microwell or well into which a liquid or fluid containing a target bio-entity, biomolecule or biological material to be sensed is flowed or otherwise introduced. A suitable biologically sensitive layer which is reactive or responsive to a target analyte may be disposed and/or formed in the microwell of well. For example, an electrical property may be modulated and/or alter in response to the biologically sensitive layer being exposed to or coming in contact with the target analyte being sensed. For example, the target analyte may be deoxyribonucleic acid (NDA) or another suitable biomolecule or biological material.

In addition, the biochip disclosed includes a reference electrode including an open-ended cavity, closely spaced to the microwell of the biosensor open-ended well, the reference electrode cavity receiving a reference material that generates a reference potential for comparison with the biosensor generated working electrode potential, i.e., biosensor well biologically sensitive layer(s) and an operatively connected semiconductor sensor, e.g. FET transistor. Relative to the working electrode of the biosensor, the reference electrodes are not affected by the substance being detected by the biosensor and are used as a reference for comparison of the biosensing results. The reference electrode arrangement also includes one or more metallization layers and/or vias to electrically connect the reference electrode cavity to one or more sensing devices, e.g., coupled to a FET transistor.

If the biochip includes an array of biosensors, and reference electrodes as disclosed herein, the biochip biological material sensing layers or surfaces that are sensitive to different bio-entities (e.g., different DNA alleles, different antibody proteins, or so forth), can provide a miniaturized laboratory for concurrently performing a set of tests.

In some suitable embodiments, the disclosed biochip includes an array of biosensors and reference electrodes, arranged such that a reference electrode open-ended cavity is positioned between and adjacent to each biosensor well opening. As will be further described below, the disclosed biosensor and reference electrode combination combines biosensor functions with a reference potential in a common semiconductor device, thereby eliminating the need to have separate biosensor chips and reference electrode chips which are bonded together. Furthermore, with the disclosed arrangement of reference electrodes proximate to a respective biosensor microwell, accuracy of biomaterial measurements can be improved because of the relative physical closeness of the reference electrode sampled reference material to the biomaterial sample source. In other words, the biosensor wells and respective reference electrode cavities are exposed to common operating environmental conditions.

In some suitable embodiments, the disclosed biochip includes a top and bottom well cup, formed by an etch process, e.g. dry etching, which is filled with biological material for the detection of target substances such as DNA, the biological material and well biosensing layers forming a conductive via electrically connecting to a bottom metallization layer(s) which is proximate to the biosensor well bottom. A biosensor device, such as a transistor gate electrode, is operatively connected to the bottom metallization layer(s), using vias or other means. A reference electrode located proximate to the biosensor well top cup provides a reference potential for comparison with the biosensor generated working potential.

In some suitable embodiments, the disclosed biochip includes a dummy structure which encases or encompasses one or all outside/perimeter/peripheral areas of the biosensor array described above, where the dummy structure includes a plurality of nonactive “reference electrode” type open-end cavities and/or associated metallization layers. This dummy structure provides overall structural integrity to the biosensor array and has the advantage of improving the overall processing reliability and quality of processing and/or dicing a wafer including a biochip array and reference electrode array combination as disclosed herein.

In some suitable embodiments, the disclosed biochip includes a biosensor and reference electrode grouping structure or grouping system. The disclosed “Grouping System” involves the simultaneous detection of various items or characteristics of a single biomaterial test substance, where Groups A, B, C, etc. each include a reference electrode(s) with different or distinct electrical potentials which are used as different reference and/or threshold standards for comparison with a specific group of biosensors, i.e. Group A biosensors, Group B biosensors, etc. Furthermore, different group reference electrodes can utilize various circuit designs to achieve the purpose of simultaneously detecting different factors of the substance being tested. For example, Groups A, B, C, etc. can serve as reference voltages for the analysis of different genetic diseases simultaneously.

In some suitable embodiments, the disclosed biochip includes a biosensor and reference electrode grouping structure where reference electrodes are combined into a single group where the electrode open-ended cavity used for receiving a reference material are combined into a single rectangular, or other shaped, open-ended cavity that is operatively associated with all the biosensors of the group. Also, with the grouping system disclosed, in some suitable embodiments, all of the reference electrodes belonging to a specific group are electrically/operatively connected to a single sensing device, such as a FET transistor. One benefit associated with this arrangement is the generation of a relatively stronger reference electrode signal which is used for comparison with the biosensors that belong to the group. For example, when a reference electrode open-well cavity spans four biosensor microwells, the reference electrode open-ended cavities have an open-ended area that is at least four times greater than a single reference electrode open-ended cavity. thereby generating a relatively stronger reference electrode potential.

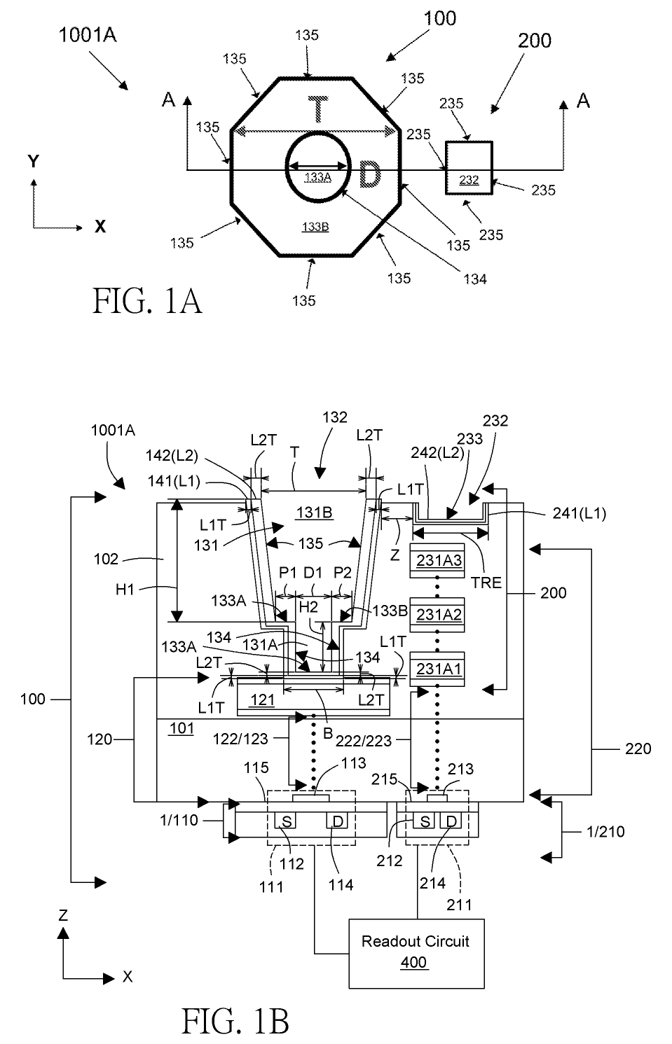

In accordance with some suitable embodiments disclosed herein, FIG. 1A diagrammatically illustrates a top view of a biological material sensing semiconductor device, including a reference electrode, in accordance with some example embodiments disclosed herein (Embodiment 1A) which has a circular or cylindrical shaped bottom well cup 131A, a polygon shaped top well cup 131B, and a polygon shaped reference electrode top or reference material receiving cavity 232; and FIG. 1B diagrammatically illustrates a cross-section view of the biological material sensing semiconductor device shown in FIG. 1A, taken along section line A-A. For ease of reference and illustrative purposes herein, in one or more of the selected FIGURES, the various elements and/or components depicted therein are shown relative to an otherwise arbitrarily chosen three-dimensional (3D) cartesian coordinate system including X, Y and Z axes as shown in the FIGURES. While consistency is maintained among and/or across the various FIGURES(unless otherwise explicitly noted), it is to be appreciated the directions and/or orientations indicated by these axes are chosen primarily for the purpose of facilitating the description provided herein, for example, to describe and/or identify relative orientations and/or directions. Unless otherwise indicated, the illustrated coordinate system and/or axes, in and of themselves, are not intended to be limiting and should not be read or interpreted as such.

In accordance with some suitable embodiments, for example as shown in FIG. 1B, the biologically sensitive semiconductor device 1001A includes a substrate 1 in and/or on which a sensor or sensing device 100 and a reference electrode 200 is formed. In some suitable embodiments, as shown in FIG. 1B, the sensor or sensing device 100 may comprise a biosensing transistor device/FET 110, for example, without limitation, such as a MOSFET, and the reference electrode is operatively connected to a transistor device/FET 210, for example, without limitation, such as a MOSFET. While the description that follows specifically describes the use of FETs as a biosensing transistor device and reference electrode transistor device, it is to be understood that the example embodiments described herein are not limited to the use of FETs and may include the use of other transistors and/or electric field type devices.

In some suitable embodiments, the biosensing FET 110 may comprise a source region 112, a drain region 114 and an active region or channel 111, each of which may be formed in the substrate 1. More specifically, as shown in FIG. 1B, the active region or channel 111 may be interposed between the source region 112 and the drain region 114. In some suitable embodiments, the substrate 1 may be a semiconductor substrate 1. In practice, the semiconductor substrate 1 may be a silicon (Si) substrate or wafer. In accordance with some embodiments, the substrate 1 may comprise, for example, without limitation, another elementary semiconductor such as germanium (Ge); a compound semiconductor including silicon carbide (SiC), gallium arsenide (GaAs), gallium phosphide (GaP), indium phosphide (InP), indium arsenide (InAs), and/or indium antimonide (InSb); an alloy semiconductor including silicon germanium (SiGe), gallium arsenide phosphide (GaAsP), aluminum indium arsenide (AlInAs), aluminum gallium arsenide (AlGaAs), gallium indium arsenide (GalnAs), gallium indium phosphide (GaInP), and/or gallium indium arsenide phosphide (GaInAsP); or combinations thereof. In various embodiments, the substrate 1 is a semiconductor-on-insulator (SOI) substrate. The SOI substrate may include a buried oxide (BOX) layer formed, for example, without limitation, by a process such as separation by implanted oxygen (SIMOX), and/or other suitable processes. The substrate 1 may be doped with a dopant such as a p-type dopant and/or an n-type dopant, for example.

In accordance with some suitable embodiments, as shown in FIG. 1B, the biosensing FET 110 may further comprise a gate structure including a gate electrode layer or gate 113 and electrically insulating layer or gate dielectric 115 and/or one or more other suitable layers. In practice, the gate electrode layer or gate 113 is formed proximate and/or next to the active region or channel 111 of the biosensing FET 110 and is separated and/or spaced apart from the active region or channel 111 of the biosensing FET 110 by the electrically insulating layer or gate dielectric 115. In some suitable embodiments, the gate electrode layer or gate 113 is polysilicon. In other suitable embodiments, the gate electrode layer or gate 113 may comprise, for example, without limitation, a metal gate electrode including materials such as, copper (Cu), tungsten (W), titanium (Ti), tantalum (Ta), chromium (Cr), platinum (Pt), silver (Ag), gold (Au), suitable metallic compounds like titanium nitride (TiN), tantalum nitride (TaN), nickel silicon (NiSi), cobalt silicon (CoSi), and/or combinations of these electrically conductive materials. In some suitable embodiments, the electrically insulating layer or gate dielectric 113 may comprise silicon oxide, for example, silicon dioxide (SiO₂). In other suitable embodiments, materials for the electrically insulating layer or gate dielectric 115 include, for example, without limitation, silicon nitride (for example, Si₃N₄), silicon oxynitride (SiOₓN_{y}), a dielectric material with a high dielectric constant (that is a high-k material), and/or combinations thereof. Some non-limiting examples of suitable high-k materials for the electrically insulating layer or gate dielectric 115 include hafnium silicate (HfSiO₄), hafnium oxide (HfO₂), zirconium oxide (ZrO₂), aluminum oxide (Al₂O₃), tantalum pentoxide (Ta₂O₅), hafnium dioxide-alumina (HfO₂-Al₂O₃) alloy, and/or combinations thereof.

In accordance with some suitable embodiments, the biosensing FET 110 may be an n-type FET (nFET) or a p-type FET (pFET). For example, in practice, the source and/or drain regions 112 and 114 may comprise one or more n-type dopants or p-type dopants depending on the type of FET 110. In practice, the biosensing FET 110 may be formed using, for example, without limitation, one or more semiconductor fabrication and/or manufacturing processes such as, photolithography and/or suitable layer pattering; ion implantation; diffusion; material deposition and/or layer forming processes including physical vapor deposition (PVD), metal evaporation or sputtering, chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), spin on coating; material removal processes such as etching including wet etching, dry etching, and plasma etching; chemical mechanical polishing (CMP); and/or other suitable semiconductor fabrication and/or manufacturing processes.

In accordance with some suitable embodiments, for example as shown in FIG. 1B, a multi-layer interconnect (MLI) structure 120 may be formed over the biosensing FET 110. In practice, the MLI structure 120 may include one or more electrically conductive lines and/or layers 121 (for example, patterned metallization layers) separated and/or spaced apart from one another by one or more interposing electrically insulating layers comprising an interlayer dielectric (ILD), and one or more electrically conductive MLI vias or plugs extending through the ILD and selectively connecting one or more of the electrically conductive lines and/or layers to one another. In some suitable embodiments, the MLI extends through the ILD between one or more of the electrically conductive lines and/or layers to form a floating gate. For example, in some suitable embodiments, the MLI structure 120 may provide physical and/or electrical connection to the sensor or sensor device 100. For example, the MLI structure 120 may provide an electrical connection to the gate electrode layer or gate 113 of the biosensing FET 110. In some suitable embodiments, the conductive lines and/or layers 121 may comprise copper, aluminum, tungsten, tantalum, titanium, nickel, cobalt, metal silicide, metal nitride, poly silicon, combinations thereof, and/or other materials possibly including one or more layers and/or linings. The interposing or inter-layer dielectric layers (for example, the ILD) may comprise silicon dioxide, fluorinated silicon glass (FGS), and/or other electrically insulating materials. In practice, the MLI structure 120 may be formed by suitable semiconductor manufacturing and/or fabrication processes, for example, including, without limitation, CVD, PVD, ALD, plating, spin-on coating, and/or other suitable processes.

Referring to the example shown in FIG. 1B, the MLI structure 120 is disposed on the substrate 1 over the FET 110. Suitably, the MLI structure 120 includes a plurality of electrically conductive lines and/or patterned layers selectively connected to one another by electrically conductive MLI vias or plugs. In some suitable embodiments, the electrically conductive lines or patterned layers comprise aluminum and/or copper. In some suitable embodiments, the electrically conductive MLI vias or plugs comprise tungsten. In other suitable embodiments, the electrically conductive MLI vias or plugs comprise copper. In practice, the one or more dielectric layers 101 forming the ILD may be disposed on the substrate 1 interposing the electrically conductive features of the MLI structure 120. The one or more dielectric layers 101 may comprise an inter-layer dielectric or ILD (sometimes referred to as an inter-metal dielectric (IMD) or IMD layer) and it may be composed of multiple ILD sub-layers. In some suitable embodiments, the one or more dielectric layers 101 may comprise silicon oxide or silicon dioxide (SiO₂). In some suitable embodiments, in addition to providing a suitable electrical connection to the gate electrode layer or gate 113 of the biosensing FET 110, the MLI structure 120 may also provide suitable electrical connections of the source and drain regions 112 and 114, respectively, of the biosensing FET 110.

In some suitable embodiments, as shown in FIG. 1B for example, a microwell or well 131 is disposed on and/or formed over the MLI structure 120, where the microwell 131 includes a bottom cup well portion 131A and a top cup well portion 131B. For example, the microwell or well 131 may be formed in a layer of intermetal dielectric material 102. The layer of intermetal dielectric material 102 may be an extension of the ILD material of the MLI structure 120 or may be an additional layer or dielectric or oxide material disposed over the MLI structure 120. In some suitable embodiments, the first ILD material 101 and the second ILD material 102 may comprise a same dielectric and/or oxide material or different dielectric and/or oxide materials. In some suitable embodiments, the layer of material 102 may comprise sub-layers that may optionally include a passivation layer (not shown) therein. The materials of the microwell or well 131 may in general be chosen for compatibility with a fluid to be tested, and for compatibility with the bio-entity (e.g., DNA or protein) contained in the fluid (or suspected to be contained in the fluid, to be determined by the testing).

Suitably, as shown in FIG. 1B, the microwell or well 131 includes a top cup well portion 131B and bottom cup well portion 131A arrangement, where the microwell open-ended bottom cup well portion is cylindrical in shape and effectively has a single side wall 134, and a bottom surface 133A. The microwell open-ended top cup well portion 131B has an octagonal shape including eight sides 135, and bottom surfaces 133B or bottom surface protrusions that form a transition opening from the top cup well portion 131B to the bottom cup well portion 131A as shown in FIG. 1B.

Suitably, as shown in FIG. 1B for example, the microwell or well 131 has an opening 132 at a first or upper end of the top well portion 131B thereof and a bottom surface or floor 133A at a second end of the bottom well portion 131A thereof, the second end being opposite the first end. In some suitable embodiments, the bottom surface or floor 133A of the microwell or well 131 is more proximate or nearer to the sensor or sensor device, for example, the biosensing FET 110, as compared to the opening 132 at the first or upper end of the microwell or well 131. According to this embodiment, the microwell or well 131 further has one or more encircling side walls or surfaces 134 and 135 extending from the bottom surface or floor 133A of the microwell or well 131 toward and/or to the opening 132 at the first or upper end of the microwell or well 131 to define an open-ended cavity into which a liquid or fluid may be selectively flowed and/or otherwise introduced through the opening 132 of the microwell or well 131 at the first or upper end thereof. In some embodiments, a cross section of the microwell or well 131 and/or open-ended cavity defined thereby, for example, when taken substantially parallel to the bottom surface or floor 133 of the microwell or well 131 (i.e., substantially parallel to the X-Y plane and/or substantially normal to the Z axis), has a polygonal shape including three or more encircling sides. For example, as seen in FIG. 1A, the microwell or well top cup well portion 131B may have, for example, eight side walls or surfaces 135 such that a top cup well portion or cavity 131B defined by the microwell or well 131 has the shape of a frustum.

More generally, in some suitable embodiments, the number of encircling side walls or surfaces 135 of the microwell top well portion 131B may be more or less than eight in practice, including a circular shaped profile that is effectively a single wall. In some suitable embodiments, the microwell or well top portion 131B has three or more side walls or surfaces 135 and the shape of the cavity defined thereby is a polygonal frustrum, for example, without limitation, a right polygonal frustrum. In some other suitable embodiments, the top microwell or well 131B has one conical side wall or surface 135 and the shape of the cavity defined thereby is a conical frustrum, for example, without limitation, a right conical frustrum. In yet other suitable embodiments, the microwell or well 131B has one cylindrical side wall or surface 135 and the shape of the cavity defined thereby is a cylinder, for example, without limitation, a right cylinder.

In some suitable embodiments, for example as seen in FIG. 1B, the encircling side walls or surfaces 135 of the top microwell or well 131B are inclined, for example, with respect to the Z axis. Accordingly, a width or diameter of the cavity (for example, measured normal or substantially normal to the Z axis) defined by the microwell or well 131B at the opening 132 or first or upper end of the microwell or well 132 has a dimension T, while a width or diameter of the cavity (for example, measured normal or substantially normal to the Z axis) defined by the bottom microwell or well 131A at second end thereof including the well bottom surface or floor 133A has a dimension B, where B is less than T. In some suitable embodiments, a first area encompassed between the one or more side walls or surfaces 135 of the microwell or well 131B at the opening 132 of the microwell or well 131B is greater than a second area encompassed between the one or more encircling side walls or surfaces 135 of the microwell or well 131B at the bottom surface 133B. Advantageously, the wider opening 132 permits liquids or fluids containing solid phase supports, for example, such as microparticles, nanoparticles, beads, or the like, carrying and/or supporting biological material or other like analytes being sensed, to be readily flowed and/or otherwise introduced into the microwell or well 131.

In accordance with some suitable embodiments, for example as shown in FIG. 1B, electrically conductive layers 121, in addition to conductive vias 122, are formed electrically connecting the bottom surface or floor 133A of the microwell or well 131. It is to be appreciated that in FIG. 1A where the biologically sensitive semiconductor device 1001A is depicted from a top view perspective, the electrically conductive metallization layers 121 resides below and/or under well coating layers 141 (L1) and 142 (L2) disposed over and/or at least partially covering the electrically conductive metallization layers 121, and accordingly, in FIG. 1B the electrically conductive via(s) 122 are indicated by a dashed or ghost line.

As described, the embodiment of FIG. 1B includes the multi-layer interconnect (MLI) structure 120 with one or multiple electrically conductive lines and/or layers 121. In some embodiments, the MLI structure 120 constitutes a single electrically conductive line and/or layer (in which case it is no longer a multi-layer interconnect, but rather a single-layer interconnect). In yet other contemplated embodiments, the single- or multi-layer interconnect structure is omitted entirely, and electrically conductive vias extend from a direct connection to the gate electrode layer or gate 113 of the biosensing FET 110 upward (for the orientation shown in FIG. 1B, i.e. along the Z-direction) so that its opposite end electrically connects to the floor 133A of the microwell or well 131.

In some suitable embodiments, the electrically conductive vias may comprise tungsten. In other suitable embodiments, the electrically conductive vias may comprise copper or another suitable electrically conductive material or metal.

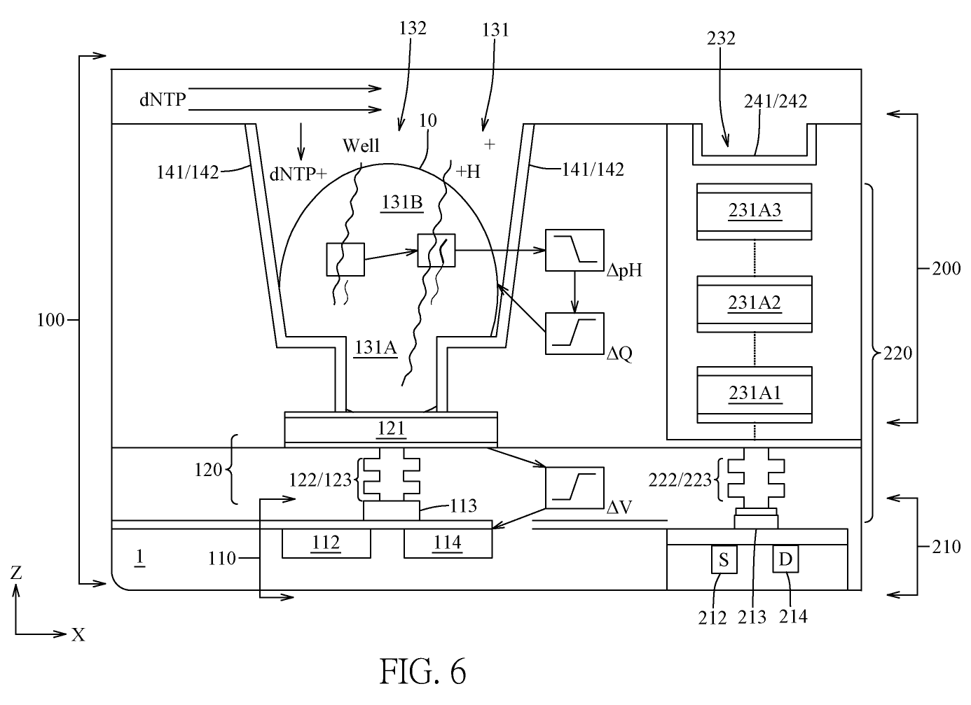

In accordance with some suitable embodiments, a biological material sensing layer (e.g., DNA template or other biological material template, not shown) is disposed on well coating layers 141(L1) and/or 142(L2) which are formed and/or disposed within the cavity defined by the microwell or well 131. In practice, the well coating layers 141(L1) and/or 142(L2) may overlay and/or at least partially cover the bottom surface 133A of the microwell or well 131 and/or at least a portion of the encircling side walls or surfaces 134 and/or 135 of the microwell or well 131. In some suitable embodiments, the biological material sensing layer is disposed on the well coating layer 141(L1) and/or 142(L2), or is disposed on a bead or other element loaded into the well 131 and containing or having coated thereon the DNA template or other biological material template (see, e.g., bead 10 in the example of FIG. 6. The DNA template or other biological material template is reactive and/or responsive to exposure to and/or contact with a target bio-entity, biomolecule, and/or target biological material being sensed. In some embodiments, the biosensor 100 with the coating(s) 141 and/or 142 is shipped to a customer, who loads the wells 131 with beads having various different biological material sensing coatings (e.g., DNA templates and/or other biological material templates) coated thereon, to create a customized biosensor chip with an array of wells sensitive to different target biological materials. In some suitable embodiments, an electrical property (for example, without limitation, such as a surface charge or a distribution of surface charge) of the well coating layer 141(L1) and/or 142(L2) and/or of the biological material sensing coating that is applied thereto) is modulated or altered in response to exposure to and/or contact with bio-entities, biomolecules, and/or target biological materials being sensed. In some suitable embodiments, the well coating layer(s) 141(L1) and/or 142(L2) may comprise TiN, Ti or another suitable material, such as a metal oxide. A biological material sensing coating (not shown) may be applied to the well coating layer 141(L1) and/or 142(L2). The biological material sensing coating serves as a biochemical template (e.g. DNA template or protein template) that includes bonded organic molecules (e.g., DNA or protein molecules) of a configuration designed to bond with high specificity to an assay target. For example, if the biologically sensitive semiconductor device 1001A is intended to assay a particular allele of a DNA strand, then the biological material sensing coating applied to the well coating layer(s) L1, L2 may include DNA or other organic molecules whose configuration bonds with high specificity to DNA strands with that particular allele.

In practice, electrically conductive metallization layers 123 and vias 122 electrically couple the interior of the well 131 coated by well coating layers 141(L1) and/or 142(L2) disposed within the microwell or well 131 to the sensor or sensing device, for example, to the gate electrode layer or gate 113 of a biosensing FET 110. In some suitable embodiments, the well coating layer 141(L1) and/or 142(L2) is electrically coupled to the gate electrode layer or gate 113 of the biosensing FET 110 by an electrically conductive via(s) through the MLI structure 120. Accordingly, the electrically conductive vias 122 may contact an upper or top-most electrically conductive line or patterned layer 121 of the MLI structure 120, while a bottom or lower-most MLI via contacts the gate electrode layer or gate 113 of the biosensing FET 110.

In accordance with some suitable embodiments, for example,

L1 (141) has a thickness L1T >0; and L2 (142) has a thickness L2T>0, where L1 is a well coating applied to the side walls of the microwell top and bottom cups 131A and 131B, respectively, as well as the bottom surfaces 133A and 133B;

microwell top cup 131B volume: π*((P1+D1+P2)/2)²*H1>0, where P1 and P2 are the dimensional length of the microwell top cup bottom extensions/protrusions 133B; D1 is the width of the opening of the microwell bottom cup 131A; and H1 is the height of the microwell top cup 131B;

microwell bottom cup 131A volume: π*(D1/2)²*H2>0, where H2 is the height of the microwell bottom cup 131A;

T>B > 0, where T is the opening width of the microwell top cup 131B that receives a biological material for testing; and B is the width of the microwell bottom cup bottom surface 133A;

H1>H2 >0.

In accordance with some suitable embodiments, for example,

P1 and P2 are about 0.1um~0.3um;

D1 is about 0.2um~0.3um;

H1 is about 0.6um~1um;

H2 is about 0.2um~0.6um;

T is about 0.6um~0.8um; and

B is about 0.1um~0.3um.

L1 (141) thickness L1T is about 50A~200A; and L2 (142) thickness L2T is about 600A~2000A. L1 and L2 material is titanium nitride (TiN) and titanium (Ti), respectively, however this is just one possible example and different materials can be used based on the required resistance and current conduction capability of the biosensing device and operatively associated circuitry, such as tantalum nitride (TaN), aluminum (Al), copper (Cu), among others.

In some suitable embodiments, the reference electrode FET 210 may comprise a source region 212, a drain region 214 and an active region or channel 211, each of which may be formed in the substrate 1. More specifically, as shown in FIG. 1B, the active region or channel 211 may be interposed between the source region 212 and the drain region 214. In some suitable embodiments, the substrate 1 may be a semiconductor substrate 1 which also used as a substrate for the forming of the biosensor 100 as previously described and will not be repeated here.

In accordance with some suitable embodiments, as shown in FIG. 1B, the reference electrode FET 210 may further comprise a gate structure including a gate electrode layer or gate 213 and electrically insulating layer or gate dielectric 215 and/or one or more other suitable layers. In practice, the gate electrode layer or gate 213 is formed proximate and/or next to the active region or channel 211 of the reference electrode FET 210 and is separated and/or spaced apart from the active region or channel 211 of the reference electrode FET 210 by the electrically insulating layer or gate dielectric 215. In some suitable embodiments, the gate electrode layer or gate 213 is polysilicon. In other suitable embodiments, the gate electrode layer or gate 213 may comprise, for example, without limitation, a metal gate electrode including materials such as, copper (Cu), tungsten (W), titanium (Ti), tantalum (Ta), chromium (Cr), platinum (Pt), silver (Ag), gold (Au), suitable metallic compounds like titanium nitride (TiN), tantalum nitride (TaN), nickel silicon (NiSi), cobalt silicon (CoSi), and/or combinations of these electrically conductive materials. In some suitable embodiments, the electrically insulating layer or gate dielectric 213 may comprise silicon oxide, for example, silicon dioxide (SiO₂). In other suitable embodiments, materials for the electrically insulating layer or gate dielectric 215 include, for example, without limitation, silicon nitride (for example, Si₃N₄), silicon oxynitride (SiOₓN_{y}), a dielectric material with a high dielectric constant (that is a high-k material), and/or combinations thereof. Some non-limiting examples of suitable high-k materials for the electrically insulating layer or gate dielectric 215 include hafnium silicate (HfSiO₄), hafnium oxide (HfO₂), zirconium oxide (ZrO₂), aluminum oxide (Al₂O₃), tantalum pentoxide (Ta₂O₅), hafnium dioxide-alumina (HfO₂-Al₂O₃) alloy, and/or combinations thereof.

In accordance with some suitable embodiments, the reference electrode FET 210 may be an n-type FET (nFET) or a p-type FET (pFET). For example, in practice, the source and/or drain regions 212 and 214 may comprise one or more n-type dopants or p-type dopants depending on the type of reference electrode FET 210. In practice, the reference electrode FET 210 may be formed using, for example, without limitation, one or more semiconductor fabrication and/or manufacturing processes such as, photolithography and/or suitable layer pattering; ion implantation; diffusion; material deposition and/or layer forming processes including physical vapor deposition (PVD), metal evaporation or sputtering, chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), spin on coating; material removal processes such as etching including wet etching, dry etching, and plasma etching; chemical mechanical polishing (CMP); and/or other suitable semiconductor fabrication and/or manufacturing processes.

In accordance with some suitable embodiments, for example as shown in FIG. 1B, a multi-layer interconnect (MLI) structure 220 may be formed over the reference electrode FET 210. In practice, the MLI structure 220 may include one or more electrically conductive lines and/or layers 231A1-231A3 (for example, patterned metallization layers) separated and/or spaced apart from one another by one or more interposing electrically insulating layers comprising an interlayer dielectric (ILD), and one or more electrically conductive MLI vias or plugs extending through the ILD and selectively connecting one or more of the electrically conductive lines and/or layers to one another. In some suitable embodiments, the MLI extends through the ILD 102 between one or more of the electrically conductive lines and/or layers to form a floating gate. For example, in some suitable embodiments, the MLI structure 220 may provide physical and/or electrical connection to the sensor or sensor device. For example, the MLI structure 220 may provide an electrical connection to the gate electrode layer or gate 213 of the reference electrode FET 210. In some suitable embodiments, the conductive lines and/or layers 231A1-231A3 may comprise copper, aluminum, tungsten, tantalum, titanium, nickel, cobalt, metal silicide, metal nitride, poly silicon, combinations thereof, and/or other materials possibly including one or more layers and/or linings. The interposing or inter-layer dielectric layers (for example, the ILD) may comprise silicon dioxide, fluorinated silicon glass (FGS), and/or other electrically insulating materials. In practice, the MLI structure 120 may be formed by suitable semiconductor manufacturing and/or fabrication processes, for example, including, without limitation, CVD, PVD, ALD, plating, spin-on coating, and/or other suitable processes.

Referring to the example shown in FIG. 1B, the MLI structure 220 is disposed on the substrate 1 over the reference electrode FET 210. Suitably, the MLI structure 220 includes a plurality of electrically conductive lines and/or patterned layers 223 selectively connected to one another by electrically conductive MLI vias or plugs 222. In some suitable embodiments, the electrically conductive lines or patterned layers 223 comprise aluminum and/or copper. In some suitable embodiments, the electrically conductive MLI vias or plugs 222 comprise tungsten. In other suitable embodiments, the electrically conductive MLI vias or plugs comprise copper. In practice, the one or more dielectric layers 101 forming the ILD may be disposed on the substrate 1 interposing the electrically conductive features of the MLI structure 220. The one or more dielectric layers 101 may comprise an inter-layer dielectric or ILD (sometimes referred to as an inter-metal dielectric (IMD) or IMD layer) and it may be composed of multiple ILD sub-layers. In some suitable embodiments, the one or more dielectric layers 101 may comprise silicon oxide or silicon dioxide (SiO₂). In some suitable embodiments, in addition to providing a suitable electrical connection to the gate electrode layer or gate 213 of the reference electrode FET 210, the MLI structure 220 may also provide suitable electrical connections of the source and drain regions 212 and 214, respectively, of the reference electrode FET 210.

In some suitable embodiments, as shown in FIG. 1B for example, an open-ended cavity 232 and one or more metallization layers 231A1-231A3 are disposed on and/or formed over the MLI structure 220. For example, the reference electrode cavity 232 may be formed in a layer of intermetal dielectric material 102. The layer of intermetal dielectric material 102 may be an extension of the ILD material of the MLI structure 220 or may be an additional layer or dielectric or oxide material disposed over the MLI structure 220. In some suitable embodiments, the first ILD material 101 and the second ILD material 102 may comprise a same dielectric and/or oxide material or different dielectric and/or oxide materials. In some suitable embodiments, the layer of material 102 may comprise sub-layers that may optionally include a passivation layer (not shown) therein. The materials of the reference electrode cavity 232 may in general be chosen for compatibility with a reference fluid to be tested.

Suitably, as shown in FIG. 1B for example, the reference electrode cavity 232 includes a cavity or well open-ended polygon shape including a four sided 235 arrangement, the reference electrode cavity 232 having an opening at an upper end of the cavity portion 232 thereof and a bottom surface or floor 233 at a second end of the cavity portion 232 thereof, the second end being opposite the first end. In some suitable embodiments, the bottom surface or floor 233 of the reference electrode cavity 232 is more proximate or nearer to the sensor or sensor device, for example, the reference electrode FET 210, as compared to the opening at the first or upper end of the reference electrode cavity 232. In some suitable embodiments, the reference electrode cavity 232 further has one or more side walls or surfaces extending from the bottom surface or floor 233 of the reference electrode cavity 232 toward and/or to the opening at the first or upper end of the cavity 232 to define an open-ended cavity into which a reference liquid or fluid may be selectively flowed and/or otherwise introduced through the reference electrode opening of the reference electrode cavity 232 at the first or upper end thereof. In some embodiments, a cross section of the reference electrode cavity 232 and/or open-ended cavity defined thereby, for example, when taken substantially parallel to the bottom surface or floor of the reference electrode cavity 232 (i.e., substantially parallel to the X-Y plane and/or substantially normal to the Z axis), has a polygonal shape including three or more sides. For example, as seen in FIG. 1A, the reference electrode cavity 232 may have, for example, four side walls or surfaces 235.

More generally, in some suitable embodiments, the number of side walls or surfaces 235 of the reference electrode cavity 232 may be more or less than four in practice, including a circular shaped profile that is effectively a single encircling wall. In some suitable embodiments, the reference electrode cavity 232 has three or more encircling side walls or surfaces 235 and the shape of the cavity defined thereby is a polygonal frustrum, for example, without limitation, a right polygonal frustrum. In some other suitable embodiments, the reference electrode cavity 232 has one encircling conical side wall or surface 235 and the shape of the cavity defined thereby is a conical frustrum, for example, without limitation, a right conical frustrum. In yet other suitable embodiments, the reference electrode cavity 232 has one encircling cylindrical side wall or surface 235 and the shape of the cavity defined thereby is a cylinder, for example, without limitation, a right cylinder.

In some suitable embodiments, for example as seen in FIG. 1B, the side walls or surfaces 235 of the reference electrode cavity 232 are inclined, for example, with respect to the Z axis. Accordingly, a width or diameter of the cavity (for example, measured normal or substantially normal to the Z axis) defined by the reference electrode cavity 232 at the opening or first or upper end of the reference electrode cavity 232 has a dimension TRE. In some suitable embodiments, TRE is from about 0.3um to 0.6um. In some suitable embodiments, a first area encompassed between the one or more side walls or surfaces 235 of the reference electrode cavity 232 at the opening of the cavity 232 is greater than a second area encompassed between the one or more side walls or surfaces 232 of the reference electrode cavity 232 at the bottom surface 233 of the reference electrode cavity 232 Advantageously, the wider opening permits reference liquids or fluids containing solid phase supports, for example, to be readily flowed and/or otherwise introduced into the reference electrode cavity 232.

In accordance with some suitable embodiments, for example as shown in FIG. 1B, electrically conductive layers 231A1-231A3, in addition to other metallization layers 223 and conductive vias 222, are formed electrically connecting the bottom surface or floor 233 of reference electrode cavity 232. It is to be appreciated that in FIG. 1A where the reference electrode 200 is depicted from a top view perspective, the electrically conductive metallization layers 231A31 resides below and/or under the reference electrode cavity 232 and cavity coating layers 241(L1) and 242 (L2) disposed over and/or at least partially covering the electrically conductive metallization layers 231A3, and accordingly, in FIG. 1B electrically conductive via(s) are indicated by a dashed or ghost line. The reference electrode cavity 232 is coupled with the one or more metallization layers 231A1-231A3, e.g., conductively by way of a via (not shown) connecting the metallization layer 231A3 to the cavity coating layers 241(L1) and 242 (L2). As the purpose of the reference electrode 200 is to produce a reference signal that is substantially independent of the concentration (or lack thereof) of the target biological material, the reference electrode cavity 232 will not be coated with the biological material sensing layer (e.g., DNA template or the like) that will be applied in the microwell or well 131. The illustrative reference electrode cavity 232 is smaller, and has a smaller interior surface area, than the microwell or well 131.

As described, the embodiment of FIG. 1B includes a multi-layer interconnect (MLI) structure 220 with one or multiple electrically conductive lines and vias 223/222. In some embodiments, the MLI structure 220 constitutes a single electrically conductive line and/or layer (in which case it is no longer a multi-layer interconnect, but rather a single-layer interconnect). In yet other contemplated embodiments, the single- or multi-layer interconnect structure is omitted entirely, and electrically conductive vias extend from a direct connection to the gate electrode layer or gate 213 of the reference electrode FET 210 upward (for the orientation shown in FIG. 1B, i.e. along the Z-direction) so that its opposite end electrically connects to the floor of the reference electrode cavity 232.

In some suitable embodiments, the electrically conductive vias may comprise tungsten. In other suitable embodiments, the electrically conductive vias may comprise copper or another suitable electrically conductive material or metal.

With particular reference to FIG. 1B, the reference electrode 200 located proximate to the biosensor well top cup 131 provides a reference potential for comparison with the biosensor-generated working potential. According to an example embodiment, the reference electrode cavity 232 side is located a spacing distance Z from the microwell top well cup side 135 of the biosensor, where Z is greater than 0.5um. This is diagrammatically shown in FIG. 1B, where a readout circuit 400 operatively connected with the biosensing FET 110 and the reference electrode FET 210 determines a biosensor output by subtracting an output of the reference electrode FET 210 (e.g., an output corresponding to the gate voltage applied by the floating reference electrode 200, which should be substantially independent of the concentration of target biological material) from an output of the biosensing FET 110 (e.g., an output corresponding to the gate voltage applied by the floating well 131, which is sensitive to the concentration of target biological material), or otherwise comparing a target biological material concentration-dependent electrical output of the biosensing FET 110 with a target biological material concentration-independent electrical output of the reference electrode FET 210. The readout circuit 400 may comprise a MOSFET or other FET-based circuit, for example implementing an operational amplifier-based comparator, subtractor, or other analog circuit for adjusting the output of the biosensing FET 110 using the output of the reference FET 210. Advantageously, in some embodiments the entire biosensor 100 including the sensing elements (i.e., biosensing FETs 110 with coupled wells 131), the reference electrodes 200 and coupled reference electrode FETs 210, and the readout circuit 400 are monolithically fabricated on a single common substrate, such as a single silicon wafer or a single silicon-on-insulator (SOI) wafer. This provides substantial advantages in compactness and accuracy (since the biosensors 110, 131 and references 200, 210 are located close together).

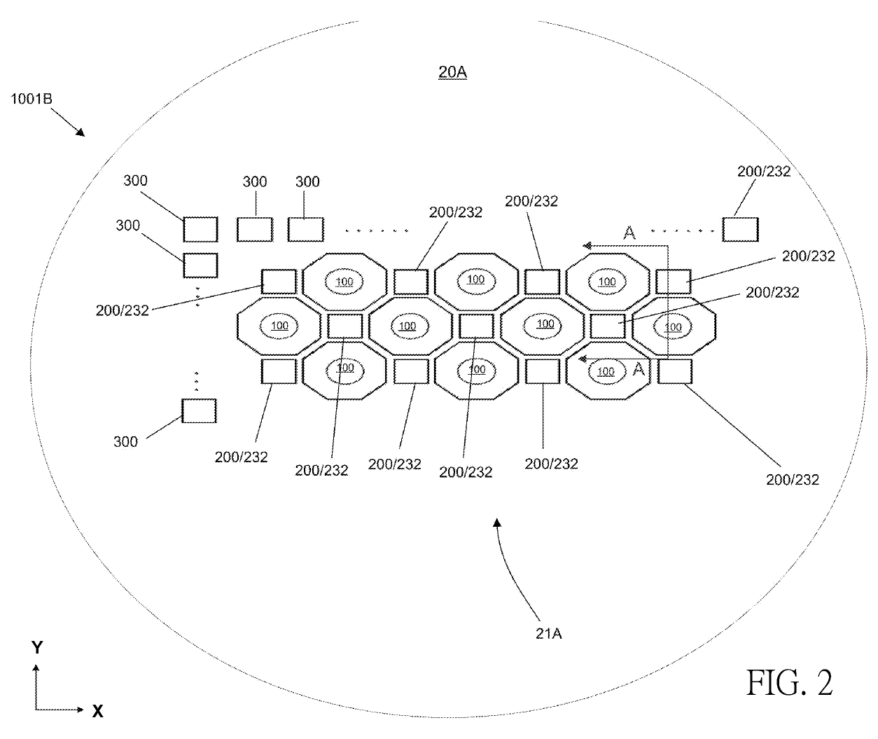

With continuing reference to FIGS. 1A and 1B, and further reference now to FIG. 2, while for simplicity and/or clarity herein, FIGS. 1A and 1B only illustrate a single biologically sensitive semiconductor device 1001A. In some suitable embodiments, a biochip may be provided, fabricated, or manufactured, for example, including an array of the biologically sensitive semiconductor devices 100 as shown in FIGS. 1A and 1B fabricated on a wafer or substrate 20, such as a silicon wafer.

In accordance with some suitable embodiments disclosed herein, FIG. 2 illustrates a top view of a biochip including a two-dimensional array 21A of biological material sensing semiconductor devices 100 in accordance with some example embodiments disclosed herein (Embodiment 1B) 1001B which have polygon shaped top well cups, polygon shaped reference electrode 200 cavities and a reference electrode dummy structure 300.

The wafer or substrate 20A suitably corresponds to the substrate 1 of FIG. 1A. The two-dimensional array 21A of the illustrative biochip extends over a surface of the wafer or substrate 20A in the X-Y plane. The illustrative array 21A shown includes a 3×3 array of biologically sensitive semiconductor devices 100, however, the array 21A may more generally be rectilinear with N×M cells where N and M are positive integers; or the two-dimensional array 21A of devices may be non-rectilinear, e.g., a hexagonal array of the biologically sensitive semiconductor devices 100 may be employed. In some embodiments, the well coating layers 141 and/or 142 may be coated with different biochemical template coatings for the different biologically sensitive semiconductor devices 100 of the array 21A. For example, the different biological template coatings may be sensitive to different proteins, different deoxyribonucleic acid (DNA) configurations, different antibodies, and/or so forth. In such a way, the biochip can constitute a miniaturized biological laboratory or “lab-on-a-chip” that can simultaneously perform a large number of tests on a given fluidic sample. As one nonlimiting illustrative example, if the biologically sensitive semiconductor devices 100 of the array 21A form a set of devices 100 that are sensitive to different alleles that are characteristic of a particular genetic disease or condition, then that disease or condition can be assayed rapidly and with high accuracy as the entire set of correlated alleles can be tested simultaneously. As another nonlimiting illustrative example, if the biologically sensitive semiconductor devices 100 of the array 21A form a set of devices that are sensitive to different antibody proteins then the biochip constitutes an antibody microarray. Suitably, the biochip may further comprise an IC including the biosensing FETs 110 along with a variety of semiconductor logic devices and/or the like to process signals received from the biosensing FETs 110 of the array 21A of biologically sensitive semiconductor devices 100. In some embodiments, the biosensing FETs 110 of the different biologically sensitive semiconductor devices 100 of the array 21A may have individually tuned FET characteristics to facilitate performing different types of biological assays (e.g., protein versus DNA detection, for example). As a nonlimiting illustrative example, the IC can include logic circuitry for analyzing the outputs of the biosensing FETs 110 of the biologically sensitive semiconductor devices 100 of the array 21A to automatically diagnose one or more diseases or medical conditions.

As shown, wafer or substrate 20A also includes reference electrodes 200, as previously described, which have reference electrode cavities 232 positioned or located adjacent and proximate to the biosensors 100 top well regions or openings. A dummy structure includes dummy reference electrodes 300 which are not operatively connected to the biosensor and reference electrodes for operation. The dummy reference electrodes 300 are located on one or more perimeter sides of the biosensor and reference electrode array to improve the fabrication of the biosensing device during various fabrication processes, including dicing, etc.

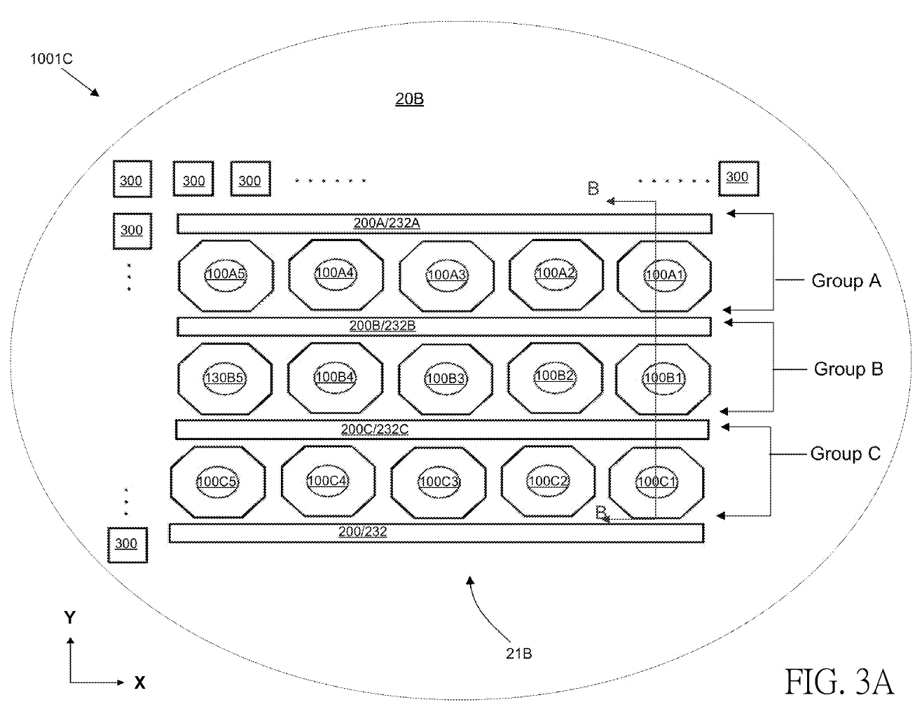

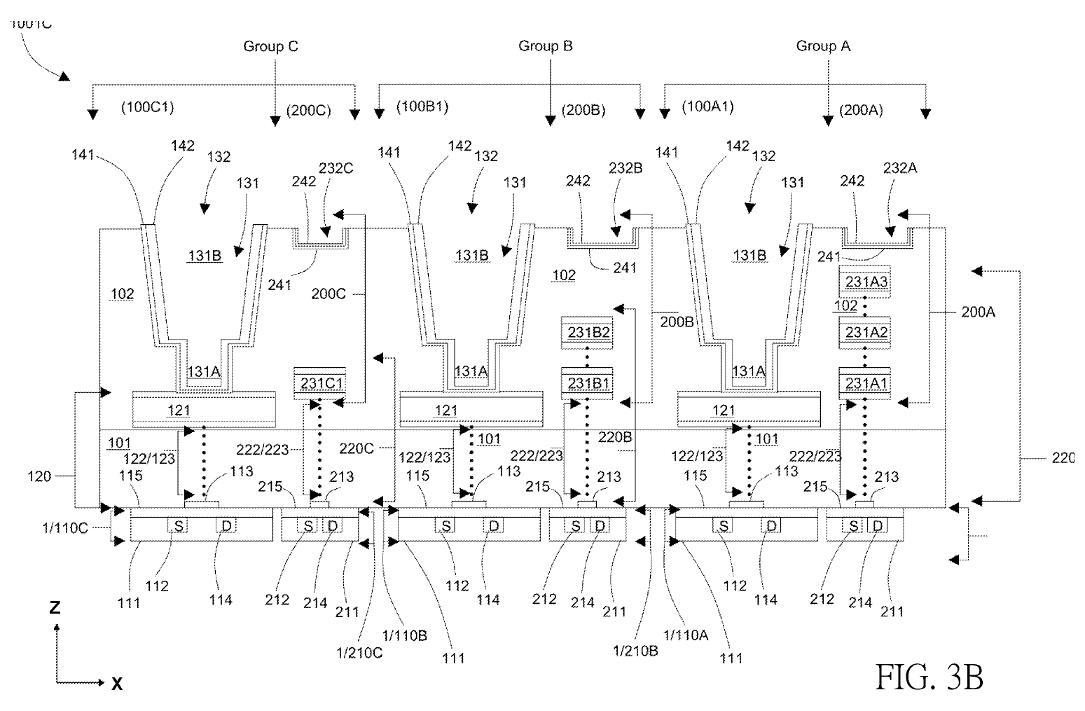

In accordance with some suitable embodiments disclosed herein, FIG. 3A illustrates a top view of another biochip including a two-dimensional array of biological material sensing semiconductor devices in accordance with some example embodiments disclosed herein (Embodiment 1C) 1001C which have biosensor 100 polygon shaped top well cups and polygon shaped reference electrode cavities 232A-232C, wherein the biochip includes grouping, and FIG. 3B illustrates a cross-section view of the biochip shown in FIG. 3A, taken along section line B-B.

According to the embodiment shown in FIGS. 3A and 3B, a grouping system, as previously described, is used to facilitate the simultaneous detection of various items in a single biomaterial test substance, where Groups A, B, C, etc. each include a reference electrode(s) with different or distinct electrical potentials which are used as different reference and/or threshold standards for comparison with a specific group of biosensors.

As shown, the disclosed biochip includes a biosensor and reference electrode grouping structure where reference electrodes are combined into a single group where the electrode open-ended cavity used for receiving a reference material are combined into a single rectangular open-ended cavity as shown, or other shaped, open-ended cavity that is operatively associated with all the biosensors of the group. Also, with the grouping system disclosed, in some suitable embodiments, all of the reference electrodes belonging to a specific group are electrically/operatively connected to a single sensing device, such as a FET transistor. One benefit associated with this arrangement is the generation of a relatively stronger reference electrode signal which is used for comparison with the biosensors that belong to the group. For example, when a reference electrode open-well cavity spans five biosensor microwells as shown in FIG. 3A, the reference electrode open-ended cavities have an open-ended area that is at least five times greater than a single reference electrode open-ended cavity. thereby generating a relatively stronger reference electrode potential.

According to the grouping example shown in FIGS. 3A and 3B,

Group A includes biosensors 100A1-100A5, and reference electrode 200A, which includes a rectangular shaped reference electrode cavity 232A;

Group B includes biosensors 100B1-100B5, and reference electrode 200B, which includes a rectangular shaped reference electrode cavity 232B; and

Group C includes biosensors 100C1-100C5, and reference electrode 200C, which includes a rectangular shaped reference electrode cavity 232C.

Furthermore, as shown in FIG. 3B, different reference electrodes can utilize various circuit designs to achieve the purpose of simultaneously detecting different factors of the substance being tested. Group A reference electrode 200A includes metallization layers 231A1-231A3 which are operatively associated with circuitry utilizing a first reference potential generated or other processing to determine characteristics of biosensing material utilizing biosensors 100A1-100A5; Group B reference electrode 200B includes metallization layers 231B1-231B2 which are operatively associated with circuitry utilizing a second reference potential generated or other processing to determine characteristics of biosensing material utilizing biosensors 100B1-100B5; and Group C reference electrode 200C includes metallization layer 231C1 which is operatively associated with circuitry utilizing a third reference potential generated or other processing to determine characteristics of biosensing material utilizing biosensors 100C1-100C5.

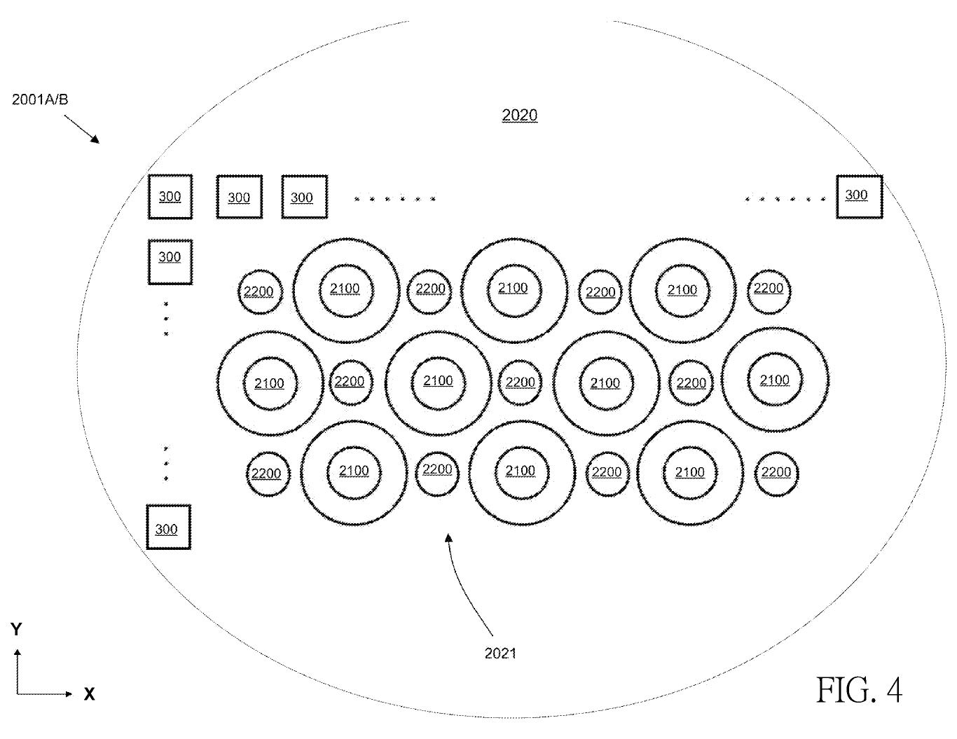

In accordance with some suitable embodiments disclosed herein, FIG. 4 illustrates a top view of another biochip including a two-dimensional array 2021 of biological material sensing semiconductor devices 2100 in accordance with some example embodiments disclosed herein (Embodiment 2A/2001A) which have circular shaped top well cups, circular shaped reference electrode 2200 cavities and dummy reference electrodes 300 (Embodiment 2B/2001B).

As shown, the wafer or substrate 2020 suitably corresponds to the substrate 1 of FIG. 1A. The two-dimensional array 2021 of the illustrative biochip extends over a surface of the wafer or substrate 2020 in the X-Y plane. The illustrative array 2021 shown includes an array of biologically sensitive semiconductor devices 2100, however, the array 2021 may more generally be rectilinear with NxM cells where N and M are positive integers; or the two-dimensional array 2021 of devices may be non-rectilinear, e.g. a hexagonal array of the biologically sensitive semiconductor devices 100, which include circular or cylindrical biosensing microwell or well top cups 131B, may be employed. In some embodiments, the well coating layers 141 and/or 142 of each biosensor 2100 may be coated with different biochemical template coatings for the different biologically sensitive semiconductor devices 2100 of the array 2021. For example, the different biological template coatings may be sensitive to different proteins, different deoxyribonucleic acid (DNA) configurations, different antibodies, and/or so forth. In such a way, the biochip can constitute a miniaturized biological laboratory or “lab-on-a-chip” that can simultaneously perform a large number of tests on a given fluidic sample. As one nonlimiting illustrative example, if the biologically sensitive semiconductor devices 2100 of the array 2021 form a set of devices 2100 that are sensitive to different alleles that are characteristic of a particular genetic disease or condition, then that disease or condition can be assayed rapidly and with high accuracy as the entire set of correlated alleles can be tested simultaneously. As another nonlimiting illustrative example, if the biologically sensitive semiconductor devices 2100 of the array 2021 form a set of devices 2100 that are sensitive to different antibody proteins then the biochip constitutes an antibody microarray. Suitably, the biochip may further comprise an IC including the biosensing FETs 110 along with a variety of semiconductor logic devices and/or the like to process signals received from the biosensing FETs 110 of the array 2021 of biologically sensitive semiconductor devices 2100. In some embodiments, the biosensing FETs 110 of the different biologically sensitive semiconductor devices 2100 of the array 2021 may have individually tuned FET characteristics to facilitate performing different types of biological assays (e.g., protein versus DNA detection, for example). As a nonlimiting illustrative example, the IC can include logic circuitry for analyzing the outputs of the biosensing FETs 110 of the biologically sensitive semiconductor devices 2100 of the array 2021 to automatically diagnose one or more diseases or medical conditions.

As shown, the wafer or substrate 2020 also includes reference electrodes 2200 as previously described with reference to FIGS. 1A, 1B and 2, reference character 200, which are positioned or located adjacent and proximate to the biosensors 2100 top well regions or openings. Here, as shown in FIG. 4, the reference electrodes 2200 are cylindrical or circle shaped, as are the biosensors 2100. A dummy structure includes dummy reference electrodes 300 which are not operatively connected to the biosensor and reference electrodes for operation. The dummy reference electrodes 300 are located on one or more outside or perimeter areas of the biosensor and reference electrode array to provide improve the fabrication of the biosensing device during various fabrication processes, including dicing, etc. According to the example embodiment shown in FIG. 4, the dummy reference electrodes 300 include rectangular or square shaped open-ended cavities, however other shapes, such as circular or other polygon shapes may be used.

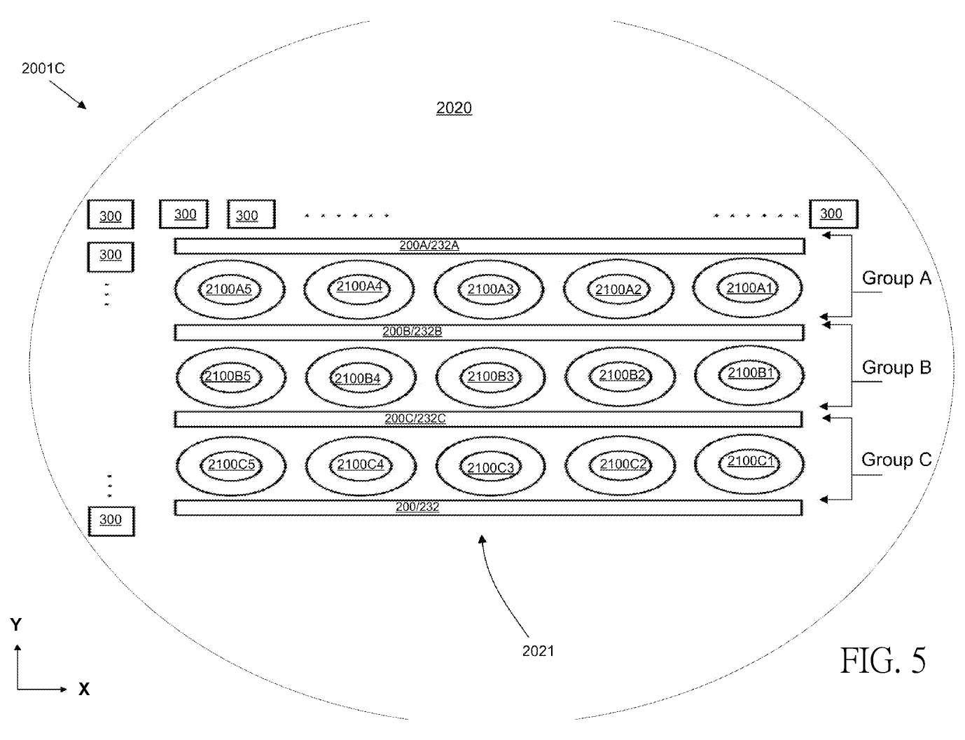

In accordance with some suitable embodiments disclosed herein, FIG. 5 illustrates a top view of another biochip including a two-dimensional array 2021 of biological material sensing semiconductor devices in accordance with some example embodiments disclosed herein wherein the biochip includes grouping of biosensors and reference electrodes (Embodiment 2C/2001C), and the biochip further includes biosensor circular shaped top well cups, rectangular or square circular shaped reference electrode cavities and a dummy reference electrode structure 300.

As previously described with reference to FIGS. 3A and 3B, embodiment 2001C includes a biosensor and reference electrode grouping arrangement, and as described with reference to FIG. 4, the biosensor microwell or well top cups are cylindrical or circle shaped.

According to the grouping example shown in FIG. 4,

Group A includes biosensors 2100A1-2100A5, and reference electrode 200A, which includes a rectangular shaped reference electrode cavity 232A;

Group B includes biosensors 2100B1-2100B5, and reference electrode 200B, which includes a rectangular shaped reference electrode cavity 232B; and

Group C includes biosensors 2100C1-2100C5, and reference electrode 200C, which includes a rectangular shaped reference electrode cavity 232C.

In accordance with some suitable embodiments disclosed herein, FIG. 6 is another diagrammatical illustration depicting a cross-section view of a biological material sensing semiconductor device in accordance with some embodiments disclosed herein, is provided here to explain some operational details of the combination biosensor 100 and reference electrode 200 embodiments disclosed herein.

In some suitable embodiments, the microwell can be significant to DNA product accuracy. In some embodiments, the microwell can be utilized as a sensing plate to detect DNA chemical liquid signa to do DNA sequencing. In some suitable embodiments, the biological material sensing semiconductor device may be manufactured, formed, constructed and/or operate similarly to the device 100 shown in FIGS. 1A and 1B and will be described with like reference character numbers. As shown in FIG. 6, a floating metal gate 121 or the like may be formed or otherwise disposed over a silicon or other suitable substrate 1 in which a source region 112, and a drain region 114 of a FET (e.g., such an ion-sensitive FET (ISFET)) may be suitably arranged. In the illustrated embodiment, the microwells 131A and 131B are disposed over the floating gate 121 suitably covered by a metal-oxide or other like well coating layer 141 and/or 142.

As shown, the well cavities 131A and 131B are suitably sized and/or dimensioned to readily receive and/or accept the bead 10 or the like when a bead bearing liquid or the like is suitably flowed over the microwell 131A. In practice, the bead 10 may act as a carrier for and/or otherwise contain a suitable DNA template, other biological material template, and/or biologically sensitive material. Suitably, in the illustrated embodiment, the well 131 is shown receiving and/or accepting the bead 10 containing the DNA template, along with the underlying sensor and/or electronics. In practice, protons (H+) may be released when nucleotides (e.g., represented here as deoxynucleotide triphosphate (dNTP)) are incorporated on the growing DNA strands, changing the pH of the well (denoted here by ΔpH). In turn, this induces a change in surface potential (denoted here by ΔQ) and a corresponding change in potential (denoted here by ΔV) of the source terminal of the underlying FET 110 or ISFET. In some suitable embodiments, an integrated circuit (IC) may consist of a suitably sizable array of sensor elements, each with a single floating gate connected to an underlying ISFET. In some suitable embodiments, high-speed addressing and/or readout may be accomplished by suitable semiconductor electronics integrated with the sensor array. In some suitable embodiments, the sensor and underlying electronics can provide a direct transduction from the incorporation event to an electronic signal, and each sensor may be used to independently and directly monitor the hydrogen ions released during nucleotide incorporation.

In some suitable embodiments, conductive layers 123 and vias 123 to further aid in electrically connecting the well bottom metallization layer(s) 121 to the gate electrode layer(s) 113 may be suitably formed using any one or more of a number CMOS and/or other suitable semiconductor manufacturing techniques and/or processes, e.g., including but not limited to suitable photolithography, masking, patterning, material deposition, metallization, etching and/or material removal steps.

As previously described with reference to FIGS. 1A and 1B, a reference electrode semiconductor structure 200 is also formed in the substrate 1 and metallization layers 231A1-231A3, and an open-ended reference electrode cavity 232 coated with well coating layers 141 and/or 142. The reference electrode 200 is operatively connected to an FET 210 including source region 212, drain region 214, a gate region/electrode 213, one or more conductive payers 223 and/or conductive vias 222, In operation, the reference electrode cavity 232 receives a reference material that generates a reference potential for comparison with the biosensor generated working electrode potential and the operatively connected semiconductor sensor, e.g., FET transistor 110. Relative to the working electrode of the biosensor, the reference electrodes are not affected by the substance being detected by the biosensor and are used as a reference for comparison of the biosensing results.

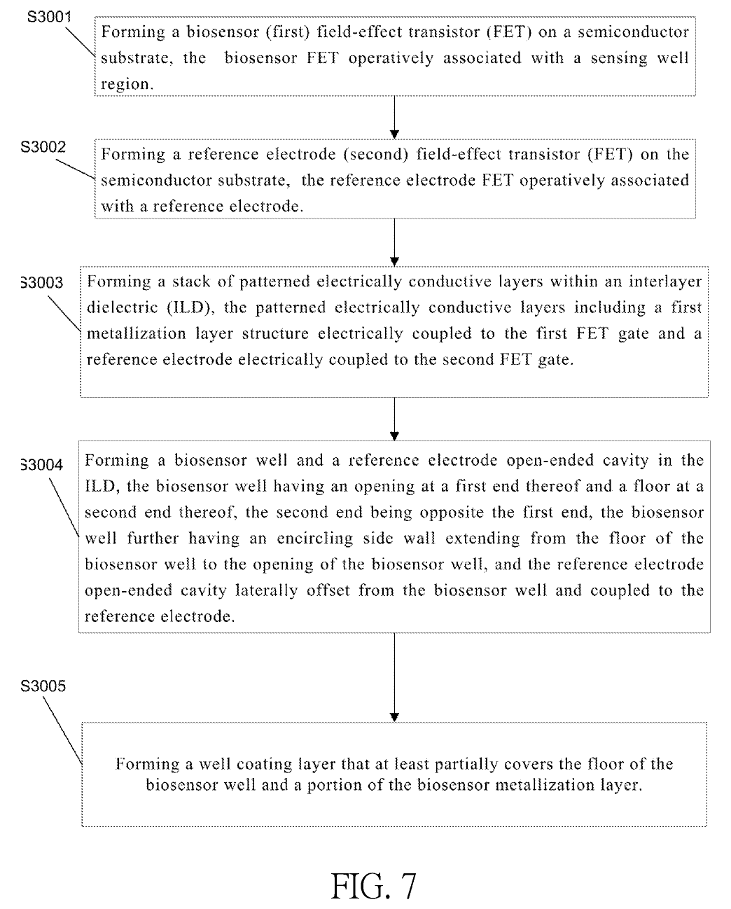

In accordance with some suitable embodiments disclosed herein, FIG. 7 is a flow chart showing a method of fabricating a biological material sensing semiconductor device in accordance with some embodiments disclosed herein.

As shown, in the illustrated embodiment, the process includes at step S3001 forming

At step S3001, in accordance with some suitable embodiments, forming a biosensor (first) field-effect transistor (FET) on a semiconductor substrate, the biosensor FET operatively associated with a sensing well region.

At step S3002, in accordance with some suitable embodiments, forming a reference electrode (second) field-effect transistor (FET) on the semiconductor substrate, the reference electrode FET operatively associated with a reference electrode.

At step S3003, in accordance with some suitable embodiments, forming a stack of patterned electrically conductive layers within an interlayer dielectric (ILD), the patterned electrically conductive layers including a first metallization layer structure electrically coupled to the first FET gate and a reference electrode electrically coupled to the second FET gate;

At step S3004, in accordance with some suitable embodiments, forming a biosensor well and a reference electrode open-ended cavity in the ILD, the biosensor well having an opening at a first end thereof and a floor at a second end thereof, the second end being opposite the first end, the biosensor well further having an encircling side wall extending from the floor of the biosensor well to the opening of the biosensor well, and the reference electrode open-ended cavity laterally offset from the biosensor well and coupled (e.g., conductively by a via) to the reference electrode;

At step S3005, in accordance with some suitable embodiments, forming a well coating layer that at least partially covers the floor of the biosensor well and a portion of the biosensor metallization layer.

It is to be understood that the process of FIG. 7 is a nonlimiting illustrative example, and that numerous variants are contemplated. For example, in one variant the steps S3001 and S3002 are integrated together. In another variant, steps S3003 and S3004 are integrated together. In another variant, at S3005, an opening of the bottom portion cup well 131A is formed by etching using photolithographic patterning to define the opening of the bottom well structure 131A and using an etchant (or combination of etchants) that remove the material of the bottom well structure 131B (e.g., etchants that are effective for etching intermetal dielectric (IMD) material) but which do not etch the copper or other metal of the electrically conductive bottom metallization layers 121 and well coating layers 141 and 142. In still another variant, steps S3004 and S3005 can include the formation of different types of reference electrodes based on the shape of the electrode area using patterns (masks) and then further processed with semiconductor manufacturing technology to form other circuits, layers and regions, etc., which may include, without limitation, one or more semiconductor fabrication and/or manufacturing processes such as, photolithography and/or suitable layer pattering; ion implantation; diffusion; material deposition and/or layer forming processes including physical vapor deposition (PVD), metal evaporation or sputtering, chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), spin on coating; material removal processes such as etching including wet etching, dry etching, and plasma etching; chemical mechanical polishing (CMP); and/or other suitable semiconductor fabrication and/or manufacturing processes.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed biosensor and reference electrode combination combines biosensor functions with a reference potential in a common semiconductor device, thereby eliminating the need to have separate biosensor chips and reference electrode chips which are bonded together. Furthermore, with the disclosed arrangement of reference electrodes proximate to a respective biosensor microwell which in turn may improve the accuracy of biomaterial measurements because of the relative physical closeness of the reference electrode sampled reference material to the biomaterial sample source.

In the following, some further embodiments are described.

In a nonlimiting illustrative embodiment, a method of fabricating a semiconductor device for sensing a target biological material, said method comprising: forming a first field-effect transistor (FET) on a semiconductor substrate, the first FET including source and drain regions with a channel region interposed therebetween and a gate structure including a gate separated from the channel region by a gate dielectric; forming a second field-effect transistor (FET) on a semiconductor substrate, the second FET including source and drain regions with a channel region interposed therebetween and a gate structure including a gate separated from the channel region by a gate dielectric; forming a stack of patterned electrically conductive layers within an interlayer dielectric (ILD), the patterned electrically conductive layers including a first metallization layer structure electrically coupled to the first FET gate and a reference electrode electrically coupled to the second FET gate; forming a well and an open-ended cavity in the ILD, the well having an opening at a first end thereof and a floor at a second end thereof, the second end being opposite the first end, the well further having an encircling side wall extending from the floor of the well to the opening of the well, and the open-ended cavity laterally offset from the well and coupled to the reference electrode; and disposing a well coating layer that at least partially covers the floor of the well and a portion of the first metallization layer.

In another nonlimiting illustrative embodiment, a biologically sensitive semiconductor device is disclosed comprising: a first sensor and a second sensor; a first well operatively associated with the first sensor and a second well operatively associated with the second sensor, each well having an opening at a first end thereof and a floor at second end thereof, the second end being more proximate to the respective first or second sensor than the first end, the well further having one or more encircling side walls extending between the floor of the well and the opening of the well such that an open-ended cavity is defined by the well into which a biological material may be selectively introduced through the opening of the well; a first well layer within the first well that at least partially covers the floor of the first well and is electrically coupled to the first sensor, and a second well layer within the second well that at least partially covers the floor of the second well and is electrically coupled to the second sensor; and a reference electrode located between the first well and the second well, the reference electrode including an open-ended cavity laterally offset from the first and second wells and coupled to a stack of one or more electrically conductive layers within an interlayer dielectric (ILD).

In another nonlimiting illustrative embodiment, a biosensor field-effect transistor (BioFET) 2-dimensional array fabricated on a semiconductor wafer structure is disclosed, the biosensor FET 2-dimensional array comprising: a plurality of BioFETs arranged in a series of rows, each of the BioFETs spaced an equal distance from adjacent BioFETs within a respective row and each of the BioFETs including: a sensor; a well, each well having an opening at a first end thereof and a floor at second end thereof, the second end being more proximate to the sensor than the first end, the well further having one or more side walls extending between the floor of the well and the opening of the well such that an open-ended cavity is defined by the well into which a biological material may be selectively introduced through the opening of the well; and a biologically sensitive material within the well, the biologically sensitive material being reactive to the biological material; and a plurality of reference electrodes arranged in a series of rows, each of the reference electrodes having metallization layer structure electrically coupled to an open-ended cavity laterally offset from an adjacent well, the reference electrode open-ended cavity defined such that a reference material may be selectively introduced through the opening of the reference electrode open-ended cavity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device for sensing a target biological material, said method comprising:
forming a first field-effect transistor (FET) on a semiconductor substrate, the first FET including source and drain regions with a channel region interposed therebetween and a gate structure including a gate separated from the channel region by a gate dielectric;
forming a second field-effect transistor (FET) on a semiconductor substrate, the second FET including source and drain regions with a channel region interposed therebetween and a gate structure including a gate separated from the channel region by a gate dielectric;
forming a stack of patterned electrically conductive layers within an interlayer dielectric (ILD), the patterned electrically conductive layers including a first metallization layer structure electrically coupled to the first FET gate and a reference electrode electrically coupled to the second FET gate;
forming a well and an open-ended cavity in the ILD, the well having an opening at a first end thereof and a floor at a second end thereof, the second end being opposite the first end, the well further having an encircling side wall extending from the floor of the well to the opening of the well, and the open-ended cavity laterally offset from the well and coupled to the reference electrode; and
disposing a well coating layer that at least partially covers the floor of the well and a portion of the first metallization layer.

2. The method of claim 1, wherein the well coating layer comprises one of titanium nitride (TiN), titanium (Ti) and a metal-oxide material.

3. The method of claim 1, wherein the well coating layer includes a titanium (Ti) layer disposed on a titanium nitride (TiN) layer which covers the one or more side walls extending from the floor of the first well toward the opening of the first well.

4. The method of claim 1, wherein the stack of patterned electrically conductive layers within the ILD further includes:
a first multi-layer interconnect (MLI) between the first FET gate and the well coating layer, the first MLI electrically coupling the well coating layer to the first FET gate, the first MLI including a stack of one or more electrically conductive layers within the ILD electrically connected to one another through one or more vias extending through the ILD between the electrically conductive layers.

5. The method of claim 4, wherein the reference electrode comprises:
a second multi-layer interconnect (MLI) electrically connected to the second FET gate, the second MLI including a stack of one or more electrically conductive layers within the ILD, the electrically conductive layers being electrically connected to one another through one or more vias extending through the ILD between the electrically conductive layers.

6. The method claim 1, wherein the reference electrode includes one or more electrically conductive layers electrically connected to each other by vias passing through the ILD.

7. The method of claim 1, wherein a first area encompassed between the one or more side walls of the first well at the opening of the first well is greater than a second area encompassed between the one or more side walls of the first well at the floor of the first well.

8. The method of claim 1, wherein the well includes an opening cup and a fluidly connected floor cup, the opening cup including one of a single continuous circular side or a polygon shaped cross-sectional profile including three or more sides.

9. The method of claim 1, wherein the reference electrode is proximately located adjacent to the first well.

10. The method of claim 1, further comprising:
forming a third field-effect transistor (FET) on the semiconductor substrate, the third FET including source and drain regions with a channel region interposed therebetween and a gate structure including a gate separated from the channel region by a gate dielectric;
forming a third metallization layer structure electrically coupled to the third FET gate;
forming a second well within a material disposed over the semiconductor substrate and the third metallization layer structure, the second well having an opening at a first end thereof and a floor at a second end thereof, the second end being opposite the first end, the well further having one or more side walls extending from the floor of the well toward the opening of the well to define an open-ended cavity; and
forming a second well coating layer that at least partially covers the floor of the second well and a portion of the third metallization layer,
wherein the reference electrode is located between the first well and the second well.

11. A biologically sensitive semiconductor device comprising:
a first sensor and a second sensor;
a first well operatively associated with the first sensor and a second well operatively associated with the second sensor, each well having an opening at a first end thereof and a floor at second end thereof, the second end being more proximate to the respective first or second sensor than the first end, the well further having one or more encircling side walls extending between the floor of the well and the opening of the well such that an open-ended cavity is defined by the well;
a first well layer within the first well that at least partially covers the floor of the first well and is electrically coupled to the first sensor, and a second well layer within the second well that at least partially covers the floor of the second well; and
a reference electrode located between the first well and the second well, the reference electrode including an open-ended cavity laterally offset from the first and second wells and coupled to a stack of one or more electrically conductive layers within an interlayer dielectric (ILD).

12. The device of claim 11, wherein the first sensor comprises a first field-effect transistor (FET) including a first gate to which the first well layer is electrically coupled and the one or more side walls of the first well are at least partially covered with the first well layer, and the second sensor comprises a second FET including a second gate to which the second well layer is electrically coupled and the one or more side walls of the second well are at least partially covered with the second well layer.

13. The device of claim 11, wherein the reference electrode open-ended cavity is proximately located near the first well, the reference electrode is electrically connected to a third FET, the third FET includes source and drain regions with a channel region interposed therebetween and a gate structure including a gate separated from the channel region by a gate dielectric, and the reference electrode includes a group of one or more multi-layer interconnect (MLI) structures electrically connected to each other, each MLI including a stack of patterned electrically conductive layers within the interlayer dielectric (ILD).

14. The device of claim 11, wherein a first area encompassed between the one or more encircling side walls of each of the first well and second well at the opening of the respective first well and second is greater than a second area encompassed between the one or more side walls of the each of the first well and second well at the floor of the respective first well and second well, and the one or more encircling side walls of the first well and second well are at least partially covered with the first and second well layers, respectively.

15. The device of claim 11,
wherein each of the first and second wells include an opening cup and a fluidly connected floor cup, the opening cup including one of a single continuous circular side or a polygon shaped cross-sectional profile including three or more sides, and
wherein the biologically sensitive semiconductor device is used to determine a presence of a target biological material in a test sample material selectively introduced into the well.

16. A biosensor field-effect transistor (BioFET) 2-dimensional array fabricated on a semiconductor wafer structure comprising:
a plurality of BioFETs arranged in a series of rows, each of the BioFETs spaced an equal distance from adjacent BioFETs within a respective row and each of the BioFETs including:
a sensor;
a well, each well having an opening at a first end thereof and a floor at
second end thereof, the second end being more proximate to the sensor than the first end, the well further having one or more encircling side walls extending between the floor of the well and the opening of the well such that an open-ended cavity is defined by the well; and
a biologically sensitive material disposed within the well electrically coupled to the sensor; and
a plurality of reference electrodes arranged in a series of rows, each of the reference electrodes having a metallization layer structure coupled to an open-ended cavity laterally offset from an adjacent well.

17. The BioFET array of claim 16, wherein a shape of the reference electrode open-ended cavity is one of rectangular, square, or circular.

18. The BioFET array of claim 16, wherein the well includes an opening cup and a fluidly connected floor cup, the opening cup including one of a single continuous circular side or a polygon shaped cross-sectional profile including three or more sides.

19. The BioFET array of claim 16, wherein the plurality of BioFETs includes a plurality of discrete groups of the plurality of BioFETs, each of the groups operatively associated with one of a plurality of distinct reference electrode configurations, each of the plurality of distinct reference electrode configurations including a distinct number of one or more multi-layer interconnect (MLI) structures electrically connected to each other, each MLI including a stack of patterned electrically conductive layers within the interlayer dielectric (ILD).

20. The BioFET array of claim 16, further comprising:
a dummy reference electrode structure including a plurality dummy reference electrodes arranged in one or both of a row and column on one or more peripheral areas on the semiconductor wafer.
